(19) United States
(12) Patent Application Publication
(10) Pub. No.: US 2025/0324808 A1
(43) Pub. Date: Oct. 16, 2025

(54) METHOD OF MANUFACTURING TRANSPARENT ELETRODE FOR SOLAR CELL USING LIQUID METAL

(71) Applicants: Hyundai Motor Company, Seoul (KR); Kia Corporation, Seoul (KR); UIF (University Industry Foundation), Yonsei University, Seoul (KR)

(72) Inventors: Yeong Hee Lee, Anyang (KR); Jang Ung Park, Seoul (KR); Su Min Kim, Seoul (KR); Won Gi Chung, Seoul (KR)

(21) Appl. No.: 18/923,363

(22) Filed: Oct. 22, 2024

(30) Foreign Application Priority Data
Apr. 15, 2024 (KR) 10-2024-0049993

(51) Int. Cl. H01L 31/18; H01L 31/0224

(52) U.S. Cl. CPC H10F 71/138; H10F 77/211

(57) ABSTRACT

A method for manufacturing a transparent electrode for a solar cell includes forming sequential layers: a lower sacrificial layer, a protective layer, and an upper sacrificial layer on a substrate. The upper sacrificial layer is partially removed to expose the protective layer, and a liquid metal layer is deposited on the exposed surfaces. The metal layer remains in a specific pattern after removing the upper sacrificial layer. A polymer layer is formed around the patterned metal layer, and the protective, metal, and polymer layers are separated from the substrate by removing the lower sacrificial layer. Finally, the protective layer is removed to produce the liquid metal transparent electrode.

### CROSS-REFERENCE TO RELATED APPLICATION

This application claims, under 35 U.S.C. § 119(a), the benefit of Korean Patent Application No. 10-2024-0049993, filed on Apr. 15, 2024, the entire contents of which are incorporated herein by reference.

### BACKGROUND

### Technical Field

The present disclosure relates to the field of solar cell technology, specifically to methods for manufacturing transparent electrodes used in solar cells. These methods involve the sequential deposition and patterning of sacrificial and protective layers, as well as the integration of liquid metal and polymer materials to create efficient and transparent conductive layers.

### Background

Gallium (Ga) is a representative liquid metal, has a low melting point of about 29.8° C., is elastic at room temperature, and has self-healing ability to restore the structure thereof even when broken. Due to these advantages, gallium is used for electrodes in electronic devices such as sensors or for flexible electrodes in the life sciences.

Recently, the use of liquid metal has been increasing in the semiconductor field, such as light emitting diodes (LEDs), etc. In particular, high-resolution patterning of liquid metal may increase the degree of integration and expand the application field. Moreover, when the line width, pitch, and the like of pattern are adjusted, the pattern cannot be recognized by human vision, and transmittance on the surface may increase, so the liquid metal may function as a transparent electrode for a solar cell.

In order to manufacture a transparent electrode using liquid metal, a deposition process and a patterning process have to be performed. However, since these deposition and patterning processes include many solution processes, there is a problem in that droplets of liquid metal are removed by surface tension in other fluids or the structure thereof is damaged during the process.

### SUMMARY OF THE DISCLOSURE

The present disclosure has been made keeping in mind the problems encountered in the related art, and is intended to provide a method of manufacturing a large-area transparent electrode for a solar cell using liquid metal.

In addition, the present disclosure is intended to provide a method of manufacturing a transparent electrode for a solar cell capable of patterning liquid metal in various shapes.

In addition, the present disclosure is intended to provide a method of manufacturing a transparent electrode for a solar cell capable of minimizing the effect of surface tension on liquid metal in a solution used in the manufacturing process.

The objects of the present disclosure are not limited to the foregoing. The objects of the present disclosure will be able to be clearly understood through the following description and to be realized by the means described in the claims and combinations thereof.

In some embodiments, a method of manufacturing a transparent electrode for a solar cell comprises sequentially forming a lower sacrificial layer, a protective layer, and an upper sacrificial layer on a substrate. A portion of the surface of the protective layer is exposed by removing a part of the upper sacrificial layer in a specific pattern shape. A metal layer comprising liquid metal is deposited on the surface of the remaining upper sacrificial layer and the exposed surface of the protective layer. The method involves leaving the metal layer in the specific pattern shape on the protective layer by removing the upper sacrificial layer with the deposited metal layer. A polymer layer is formed to surround the metal layer with the specific pattern shape, and the protective layer, metal layer, and polymer layer are separated from the substrate by removing the lower sacrificial layer, followed by removing the protective layer to manufacture the liquid metal transparent electrode comprising the metal layer and the polymer layer.

In some embodiments, each of the lower sacrificial layer and the upper sacrificial layer comprises a photoresist. The lower and upper sacrificial layers may comprise lift-off resist (LOR) or poly(methyl methacrylate) (PMMA), or a combination thereof. The protective layer may comprise a hydrophobic polymer, such as parylene-C, with a thickness of about 0.5 μm to 3 μm.

The specific pattern shape may include a stripe shape, a branch shape, or a grid shape with a line width of about 1 μm to 10 μm. The liquid metal may comprise a eutectic gallium-indium alloy (EGaIn). The polymer layer may be a transparent elastomer or a thermosetting polymer, such as polydimethylsiloxane (PDMS) or thermoplastic polyurethane elastomer (TPE). The protective layer may be removed by dry etching using oxygen plasma.

In some embodiments, a method of manufacturing a transparent electrode for a solar cell involves forming a lower sacrificial layer on a substrate, followed by forming a protective layer and an upper sacrificial layer. The upper sacrificial layer is patterned to expose a portion of the protective layer. A metal layer comprising liquid metal is deposited on the patterned upper sacrificial layer and the exposed portion of the protective layer. The upper sacrificial layer is removed to leave the metal layer in a patterned shape on the protective layer, and a polymer layer is formed over the patterned metal layer. The protective layer, metal layer, and polymer layer are separated from the substrate by removing the lower sacrificial layer, followed by removing the protective layer to produce the transparent electrode.

In some embodiments, each of the lower and upper sacrificial layers comprises lift-off resist (LOR) or poly(methyl methacrylate) (PMMA). The protective layer may comprise parylene-C, and the liquid metal may comprise a eutectic gallium-indium alloy (EGaIn).

In some embodiments, a method of manufacturing a transparent electrode for a solar cell comprises forming a lower sacrificial layer on a substrate, a protective layer on the lower sacrificial layer, and an upper sacrificial layer on the protective layer. The upper sacrificial layer is patterned to expose a portion of the protective layer, and a metal layer comprising liquid metal is deposited on the patterned upper sacrificial layer and the exposed portion of the protective layer. A polymer layer is formed over the patterned metal layer, and the protective layer, metal layer, and polymer layer are separated from the substrate by removing the lower sacrificial layer. The polymer layer is cured to form a transparent elastomeric matrix, thereby forming the transparent electrode. The polymer layer may be cured using UV light and may comprise polydimethylsiloxane (PDMS).

As discussed, the method and system suitably include use of a controller or processer.

### BRIEF DESCRIPTION OF THE DRAWINGS

The above and other features of the present disclosure will now be described in detail referring to certain exemplary embodiments thereof illustrated in the accompanying drawings, which are given hereinbelow by way of illustration only, and thus are not limitative of the present disclosure, and wherein:

FIG. 1 shows a transparent electrode for a solar cell manufactured according to the present disclosure;

FIG. 2 shows a process of manufacturing a transparent electrode for a solar cell according to the present disclosure;

FIG. 3 shows forming a lower sacrificial layer, a protective layer, and an upper sacrificial layer on a substrate;

FIG. 4 shows patterning the upper sacrificial layer;

FIG. 5 shows depositing a metal layer;

FIG. 6 shows patterning the metal layer;

FIG. 7 shows forming a polymer layer;

FIG. 8 shows separating the protective layer, the metal layer, and the polymer layer from the substrate;

FIG. 9 shows manufacturing a liquid metal transparent electrode by removing the protective layer;

FIG. 10 shows optical microscope images of the transparent electrode according to Example at different magnifications;

FIG. 11 shows optical microscope images of the transparent electrode according to Comparative Example at different magnifications;

FIG. 12 shows positions for measuring sheet resistance of Example and Comparative Example;

FIG. 13 shows results of measurement of sheet resistance at a total of 5 points in Example;

FIG. 14 shows results of measurement of sheet resistance at a total of 5 points in Comparative Example; and

FIG. 15 shows results of measurement of visible light transmittance of a transparent electrode depending on the presence or absence of a protective layer.

### DETAILED DESCRIPTION

The above and other objects, features and advantages of the present disclosure will be more clearly understood from the following preferred embodiments taken in conjunction with the accompanying drawings. However, the present disclosure is not limited to the embodiments disclosed herein, and may be modified into different forms. These embodiments are provided to thoroughly explain the disclosure and to sufficiently transfer the spirit of the present disclosure to those skilled in the art.

Throughout the drawings, the same reference numerals will refer to the same or like elements. For the sake of clarity of the present disclosure, the dimensions of structures are depicted as being larger than the actual sizes thereof. It will be understood that, although terms such as “first”, “second”, etc. may be used herein to describe various elements, these elements are not to be limited by these terms. These terms are only used to distinguish one element from another element. For instance, a “first” element discussed below could be termed a “second” element without departing from the scope of the present disclosure. Similarly, the “second” element could also be termed a “first” element. As used herein, the singular forms are intended to include the plural forms as well, unless the context clearly indicates otherwise.

It will be further understood that the terms “comprise”, “include”, “have”, etc., when used in this specification, specify the presence of stated features, integers, steps, operations, elements, components, or combinations thereof, but do not preclude the presence or addition of one or more other features, integers, steps, operations, elements, components, or combinations thereof. Also, it will be understood that when an element such as a layer, film, area, or sheet is referred to as being “on” another element, it may be directly on the other element, or intervening elements may be present therebetween. Similarly, when an element such as a layer, film, area, or sheet is referred to as being “under” another element, it may be directly under the other element, or intervening elements may be present therebetween.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. As used herein, the term “and/or” includes any and all combinations of one or more of the associated listed items. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Unless otherwise specified, all numbers, values, and/or representations that express the amounts of components, reaction conditions, polymer compositions, and mixtures used herein are to be taken as approximations including various uncertainties affecting measurement that inherently occur in obtaining these values, among others, and thus should be understood to be modified by the term “about” in all cases. Furthermore, when a numerical range is disclosed in this specification, the range is continuous, and includes all values from the minimum value of said range to the maximum value thereof, unless otherwise indicated. Moreover, when such a range pertains to integer values, all integers including the minimum value to the maximum value are included, unless otherwise indicated.

In the present specification, when a range is described for a variable, it will be understood that the variable includes all values including the end points described within the stated range. For example, the range of “5 to 10” will be understood to include any subranges, such as 6 to 10, 7 to 10, 6 to 9, 7 to 9, and the like, as well as individual values of 5, 6, 7, 8, 9 and 10, and will also be understood to include any value between valid integers within the stated range, such as 5.5, 6.5, 7.5, 5.5 to 8.5, 6.5 to 9, and the like. Also, for example, the range of “10% to 30%” will be understood to include subranges, such as 10% to 15%, 12% to 18%, 20% to 30%, etc., as well as all integers including values of 10%, 11%, 12%, 13% and the like up to 30%, and will also be understood to include any value between valid integers within the stated range, such as 10.5%, 15.5%, 25.5%, and the like.

Existing solar cells are configured such that the upper electrode is opaque, but the upper electrode must also be transparent for light to pass therethrough and reach heterogeneous cells. Recently, research has been carried out into replacing the upper electrode with a transparent electrode. However, most transparent electrodes have high sheet resistance, lowering light conversion efficiency of solar cells or transmittance, which is undesirable.

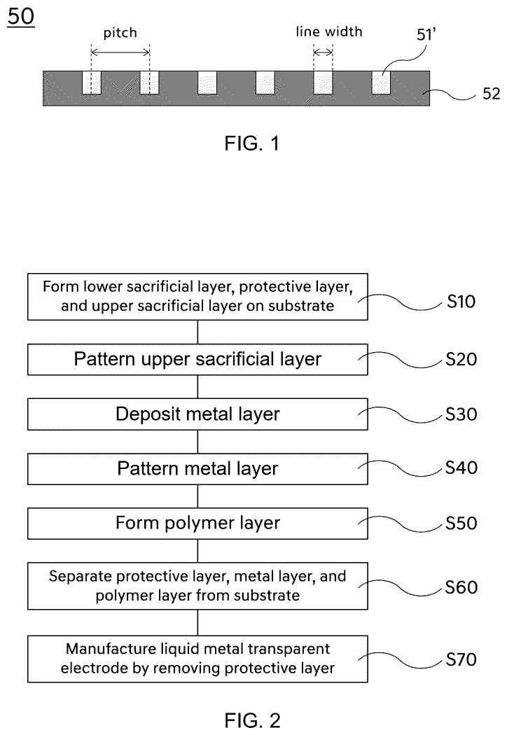

To solve these disadvantages, the present disclosure pertains to a method of manufacturing a transparent electrode for a solar cell. FIG. 1 shows a transparent electrode for a solar cell manufactured according to the present disclosure, and FIG. 2 shows a process of manufacturing a transparent electrode for a solar cell according to the present disclosure.

The method of manufacturing the transparent electrode 50 according to FIG. 2 may include sequentially forming a lower sacrificial layer 20, a protective layer 30, and an upper sacrificial layer 40 on a substrate 10 (S10), exposing a portion of the surface of the protective layer 30 by removing a portion of the upper sacrificial layer 40 in a specific pattern shape (S20), depositing a metal layer 51 containing liquid metal on the surface of the remaining upper sacrificial layer 40′ and the surface of the protective layer 30 that is exposed (S30), leaving a metal layer 51′ having the specific pattern shape on the protective layer 30 by removing the upper sacrificial layer 40′ with the metal layer 51 deposited thereon (S40), forming a polymer layer 52 to surround the metal layer 51′ having the specific pattern shape (S50), separating the protective layer 30, the metal layer 51′, and the polymer layer 52 from the substrate 10 by removing the lower sacrificial layer 20 (S60), and manufacturing a liquid metal transparent electrode 50 including the metal layer 51′ and the polymer layer 52 by removing the protective layer 30 (S70).

Below is a detailed description of individual steps.

### Sequentially Forming Lower Sacrificial Layer, Protective Layer, and Upper Sacrificial Layer on Substrate (S10)

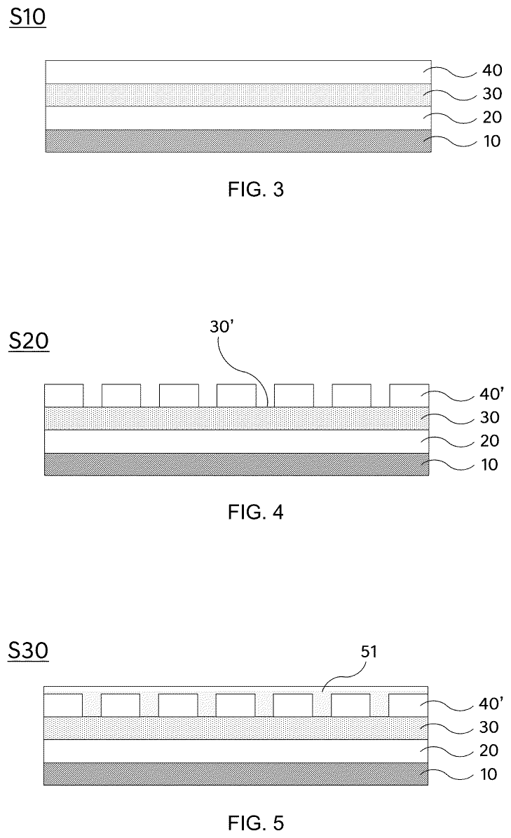

FIG. 3 shows forming the lower sacrificial layer 20, the protective layer 30, and the upper sacrificial layer 40 on the substrate 10. This step (S10) serves to prepare a basis for later stacking or patterning the metal layer 51 by sequentially applying or stacking the lower sacrificial layer 20, the protective layer 30, and the upper sacrificial layer 40 onto the substrate 10.

The substrate 10 is not particularly limited, so long as it is able to support a lower sacrificial layer 20, a protective layer 30, an upper sacrificial layer 40, a metal layer 51, and a polymer layer 52 in subsequent steps (for example, S20 to S50). For example, a silicon wafer, a silicon oxide wafer, etc. may be used.

Generally, a sacrificial layer is a layer deposited between any one layer and a material to be separated therefrom. The sacrificial layer may play a role in easily detaching the material to be separated due to reduced adhesion between the layer and the material to be separated therefrom by removing the sacrificial layer during the process. Also, the sacrificial layer may serve as a template for forming a pattern on any one layer.

Referring to FIG. 3, the lower sacrificial layer 20 may be formed by applying an easily removable material onto any one surface of the substrate 10. The lower sacrificial layer 20 is not particularly limited, so long as it is a layer that is able to separate the substrate 10 and the protective layer 30 by an exposure process or a solution process in the subsequent step.

For example, the lower sacrificial layer 20 may be formed by applying a polymer material such as a photoresist, which may be removed by an exposure process, onto the substrate 10.

The photoresist may include, for example, a lift-off resistor (LOR), particularly LOR-0.5A, LOR-0.7A, LOR-1A, LOR-3A, LOR-5A, poly(methyl methacrylate) (PMMA), etc., more particularly any one selected from the group consisting of LOR-3A, PMMA (poly(methyl methacrylate)), and combinations thereof.

A process of applying the lower sacrificial layer 20 onto the substrate 10 may include a typical coating process in the solar cell field, for example, spin coating, blade coating, or bar coating.

The thickness of the lower sacrificial layer 20 is not particularly limited, and may be appropriately adjusted to a level to be easily removable in the subsequent step while connecting the substrate 10 and the protective layer 30.

The lower sacrificial layer 20 may be applied onto the substrate 10 and a protective layer 30 may be formed thereon. In one embodiment, the protective layer 30 may include a hydrophobic polymer. Preferably, the protective layer 30 includes parylene-C. Since the protective layer 30 is interposed between the lower sacrificial layer 20 and the upper sacrificial layer 40 and is hydrophobic, the effect of surface tension may be minimized in the solution used during deposition and patterning of the metal layer 51.

In one embodiment, the thickness of the protective layer 30 may be 0.5 μm to 3 μm. If the thickness of the protective layer 30 is less than 0.5 μm, it may be difficult to suppress the effect of surface tension. On the other hand, if the thickness of the protective layer 30 exceeds 3 μm, the material for the protective layer 30, which will eventually be removed, may be wasted, and the time required for removal may increase, reducing the overall process efficiency.

After forming the protective layer 30, an upper sacrificial layer 40 may be applied onto the protective layer 30. The upper sacrificial layer 40 may later serve as a template in the process of forming the metal layer 51′ having the specific pattern shape. To this end, the upper sacrificial layer 40 is not particularly limited, so long as it serves as a template for the metal layer 51′ having a specific shape by an exposure process or a solution process and may be ultimately removed.

In addition, since the upper sacrificial layer 40 has substantially the same composition or characteristics as the lower sacrificial layer 20 except for the formation position, a redundant description thereof will be omitted.

### Exposing Portion of Surface of Protective Layer by Removing Portion of Upper Sacrificial Layer in Specific Pattern Shape (S20)

FIG. 4 shows patterning the upper sacrificial layer 40. After sequentially forming the lower sacrificial layer 20, the protective layer 30, and the upper sacrificial layer 40 on the substrate 10 (S10), a portion of the upper sacrificial layer 40 may be removed in a specific pattern shape. When a portion of the upper sacrificial layer 40 is removed in a specific pattern shape, a portion of the surface of the protective layer may be exposed 30′ as shown in FIG. 4.

The process of removing a portion of the upper sacrificial layer 40 is not particularly limited, and any appropriate process capable of removing the material for the sacrificial layer may be adopted. When the sacrificial layer includes a photoresist, a portion of the upper sacrificial layer 40 may be removed through exposure or ashing.

For example, when the photoresist is a positive type, a masking tape or the like may be placed in a specific pattern shape on the upper sacrificial layer 40 and then an exposure process may be performed, whereby crosslinking of the exposed portion is separated. Thereafter, by adding a decomposition solution or a developer, the exposed portion of the upper sacrificial layer 40 may be easily removed. A portion of the surface of the protective layer from which the upper sacrificial layer 40 has been removed is exposed 30′ to the outside.

The remaining upper sacrificial layer 40′ may serve as a template for the metal layer 51′ having the specific pattern shape that is ultimately obtained, which will be described later.

Depositing Metal Layer Containing Liquid Metal on Surface of Remaining Upper Sacrificial Layer and Surface of Protective Layer that is Exposed (S30)

FIG. 5 shows depositing the metal layer 51. The metal layer 51 may be formed by thermal evaporation.

Specifically, the substrate 10, the lower sacrificial layer 20, the protective layer 30, and the upper sacrificial layer 40′ remaining on the protective layer 30 may be added to a deposition device. Thereafter, a source of liquid metal may be added to the deposition device.

As such, the liquid metal may include gallium (Ga) and indium (In). Gallium (Ga) and indium (In) may be added in appropriate amounts depending on the composition of the desired liquid metal, the thickness of the metal layer 51, etc. Preferably, the liquid metal includes a material having high metal conductivity and excellent elasticity, for example, a eutectic gallium-indium alloy (EGaIn), to improve charge uniformity.

Gallium (Ga) and indium (In) may be heated simultaneously, and the deposition rate may be adjusted so that both gallium (Ga) and indium (In) added to the deposition device are deposited. Gallium (Ga) and indium (In) may be simultaneously heated to deposit both gallium (Ga) and indium (In) on the surface of the remaining upper sacrificial layer 40′ and the surface 30′ of the protective layer that is exposed.

Preferably, the eutectic gallium-indium alloy (EGaIn) is deposited on the surface of the remaining upper sacrificial layer 40′ and the surface 30′ of the protective layer that is exposed.

Leaving Metal Layer Having Specific Pattern Shape on Protective Layer by Removing Upper Sacrificial Layer with Metal Layer Deposited Thereon (S40)

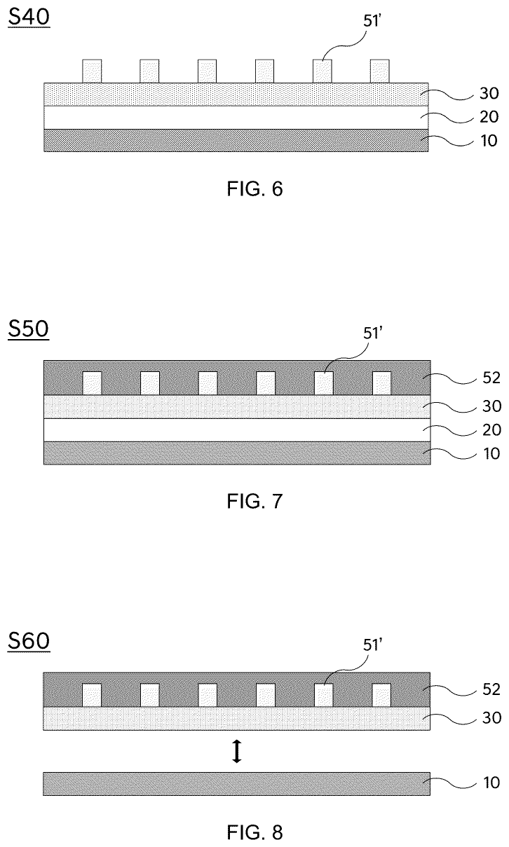

FIG. 6 shows patterning the metal layer 51. A metal layer 51′ having the same pattern as the upper sacrificial layer 40′ removed in a specific pattern shape may be left by lifting-off the upper sacrificial layer 40′ and the metal layer 51 formed on the upper sacrificial layer 40′.

The lift-off process may include removing the remaining upper sacrificial layer 40′, which is a template for the metal layer 51′ having the specific pattern shape, and may be appropriately performed depending on the material of the remaining upper sacrificial layer 40′. When the remaining upper sacrificial layer 40′ includes a photoresist, the lift-off process may be performed through exposure or ashing.

When the photoresist is a positive type, crosslinking of the remaining upper sacrificial layer 40′ may be separated by an exposure process on the metal layer 50, after which a decomposition solution or developer is added, whereby the remaining upper sacrificial layer 40′ and the metal layer deposited thereon are removed together.

In one embodiment, the specific pattern shape may include a stripe shape, a branch shape, or a grid shape. Since the liquid metal of the metal layer 51′ has a stripe shape, branch shape, or grid shape, the outermost portion of the structure may further include a thin oxide layer due to surface oxidation. The thin oxide layer may play a role in improving elasticity together with the polymer layer 52, and also may have self-healing properties.

In one embodiment, the line width of the specific pattern may be 1 μm to 10 μm. Also, the pitch of the specific pattern may be 10 μm to 200 μm. If the line width of the specific pattern exceeds 10 μm or the pitch thereof is less than 10 μm, transparency of the transparent electrode 50 may decrease. On the other hand, if the line width of the specific pattern is less than 1 μm or the pitch thereof exceeds 200 μm, sheet resistance may increase.

### Forming Polymer Layer to Surround Metal Layer Having Specific Pattern Shape (S50)

FIG. 7 shows forming the polymer layer 52 to surround the metal layer 51′ having the specific pattern shape. As such, since the protective layer 30 is present under the metal layer 51′ having the specific pattern shape as shown in FIG. 7, forming the polymer layer 52 to surround the metal layer 51′ may be understood as surrounding the top and sides of the metal layer 51′.

The process of forming the polymer layer 52 to surround the metal layer 51′ having the specific pattern shape may be performed by any process commonly used in the solar cell field. For example, spin coating or bar coating may be used.

In one embodiment, the polymer layer 52 may include a transparent elastomer. The polymer layer 52 includes elastomer, thus maintaining elasticity, and is also included in the transparent electrode 50, so it is preferable to use a transparent material with high light transmittance.

Moreover, the polymer layer 52 may include a thermosetting polymer. For example, the polymer layer 52 may include any one selected from the group consisting of polydimethylsiloxane (PDMS), thermoplastic polyurethane elastomer (TPE), and combinations thereof. Preferably, the polymer layer includes PDMS, which is transparent in the visible and infrared spectral ranges. The thermosetting polymer may be applied to cover the top and sides of the metal layer 51F and then cured to form the polymer layer 52.

The polymer layer 52 is able to maintain elasticity while protecting the metal layer 51′ against external force and chemical exposure, and includes a transparent elastomer to improve light transmittance, thereby imparting bifacial properties.

Separating Protective Layer, Metal Layer, and Polymer Layer from Substrate 10 by Removing Lower Sacrificial Layer (S60)

FIG. 8 shows separating the protective layer 30, the metal layer 51′, and the polymer layer 52 from the substrate 10. The process of separating the protective layer 30, the metal layer 51′, and the polymer layer 52 from the substrate 10 may include removing the lower sacrificial layer 20 interposed between the substrate 10 and the protective layer 30.

The lower sacrificial layer 20 may be removed by an exposure process or a solution process. Preferably, a solution process is performed. In the solution process, a photoresist remover solution capable of removing the lower sacrificial layer 20 is used. As a non-limiting example, the remover solution may include any one selected from the group consisting of mr-Rem 700, acetone, and combinations thereof.

Here, since the exposure process is substantially the same as described above, a redundant description thereof will be omitted.

### Manufacturing Liquid Metal Transparent Electrode Including Metal Layer and Polymer Layer by Removing Protective Layer (S70)

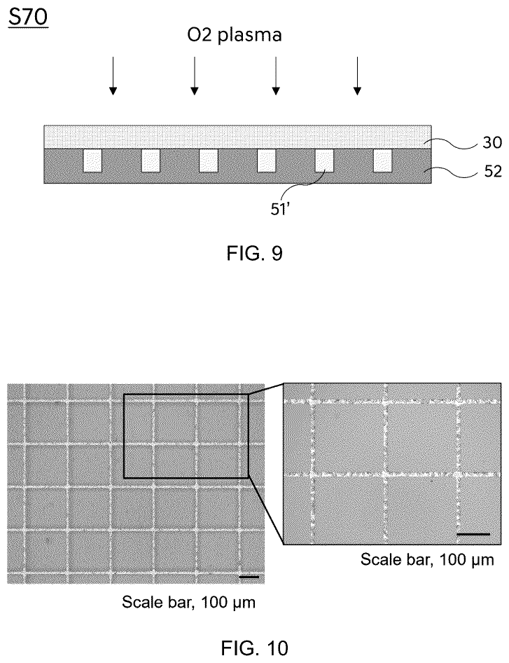

FIG. 9 shows manufacturing the liquid metal transparent electrode 50 by removing the protective layer 30. The protective layer 30 may be removed using a dry etching process. The dry etching process may include a plasma etching process. As such, the plasma may be oxygen (O₂) plasma or halogen plasma, preferably oxygen plasma.

Dry etching of the protective layer 30 using oxygen plasma may be performed by a process commonly used in the solar cell field.

In this way, by removing the protective layer 30 using oxygen plasma, a transparent electrode 50 for a solar cell including the metal layer 51′ having the specific pattern shape and the polymer layer 52 surrounding the same may be manufactured.

According to the present disclosure, the metal layer 51F may be formed by depositing the liquid metal on the substrate 10 or the upper sacrificial layer 40 rather than printing the same, facilitating large-area formation. In addition, the transparent electrode 50 may be manufactured by depositing the metal layer 51′ on a template resulting from removing the upper sacrificial layer 40 by an exposure process, so that various pattern shapes may be formed compared to existing printing processes.

In addition, the printing process requires a long process time in proportion to the area of the transparent electrode 50, but the method of manufacturing the transparent electrode 50 according to the present disclosure includes depositing liquid metal, so the process time is the same regardless of the area and thus manufacturing efficiency is very high.

Also, in the printing process, pattern reproducibility may vary depending on a nozzle, a distance between the nozzle and the substrate 10, a temperature, humidity, pneumatic pressure or voltage applied to the nozzle, vibration of the substrate 10, state of the solution, etc. However, the transparent electrode 50 according to the present disclosure has excellent reproducibility because the line width and pitch of the pattern are maintained uniformly by the mask used when removing the upper sacrificial layer 40.

In addition, since the transparent electrode 50 according to the present disclosure contains liquid metal, it is elastic at room temperature and has self-healing ability.

Moreover, damage to the liquid metal electrode may be minimized by introducing the protective layer 30 including a hydrophobic polymer in the process of manufacturing the transparent electrode 50. Accordingly, in manufacturing the transparent electrode 50, the process yield may be improved and electrochemical performance thereof may be improved.

A better understanding of the present disclosure may be obtained through the following example and comparative example. However, these examples are not to be construed as limiting the technical spirit of the present disclosure.

### Example

(1) A silicon wafer was prepared as a substrate, and a lower sacrificial layer containing LOR (lift-off resist) 3A was applied onto the substrate by spin coating. The spin coating was performed at 1000 rpm to 4000 rpm for 20 to 40 seconds. Thereafter, a protective layer containing parylene-C was applied to a thickness of about 2 μm onto the lower sacrificial layer. Then, an upper sacrificial layer was applied onto the protective layer in the same manner as the lower sacrificial layer.

(2) A portion of the upper sacrificial layer was removed in a grid shape by an exposure process.

(3) A eutectic gallium (Ga)-indium (In) alloy (EGaIn) was deposited as liquid metal on the surface of the remaining upper sacrificial layer and the surface of the protective layer that was exposed, forming a metal layer.

(4) The upper sacrificial layer with the metal layer deposited thereon was subjected to an exposure process, leaving a metal layer having the grid shape on the protective layer.

(5) PDMS, which is a transparent curable elastomer to form a polymer layer, was disposed to surround the top and sides of the metal layer having the grid shape by spin coating, forming a polymer layer.

(6) The lower sacrificial layer was removed using mr-Rem 700, which is a sacrificial layer remover solution, separating the protective layer, the metal layer, and the polymer layer from the substrate.

(7) A dry etching process using oxygen plasma was performed in the direction of the protective layer on the separated protective layer, metal layer, and polymer layer, removing the protective layer.

### Comparative Example

(1) A silicon wafer was prepared as a substrate, and a lower sacrificial layer containing LOR (lift-off resist) 3A was applied onto the substrate by spin coating. The spin coating was performed at 1000 rpm to 4000 rpm for 20 to 40 seconds. Thereafter, an upper sacrificial layer was applied onto the lower sacrificial layer in the same manner as the lower sacrificial layer.

(2) A portion of the upper sacrificial layer was removed in a grid shape by an exposure process.

(3) A eutectic gallium (Ga)-indium (In) alloy (EGaIn) was deposited as liquid metal on the surface of the remaining upper sacrificial layer and the surface of the lower sacrificial layer that was exposed, forming a metal layer.

(4) The upper sacrificial layer with the metal layer deposited thereon was removed by an exposure process, leaving a metal layer having the grid shape on the lower sacrificial layer.

(5) PDMS, which is a transparent curable elastomer to form a polymer layer, was disposed to surround the top and sides of the metal layer having the grid shape by spin coating, forming a polymer layer.

(6) The lower sacrificial layer was removed using mr-Rem 700, which a sacrificial layer remover solution, separating the metal layer and the polymer layer from the substrate.

### Test Example 1—Optical Microscopy

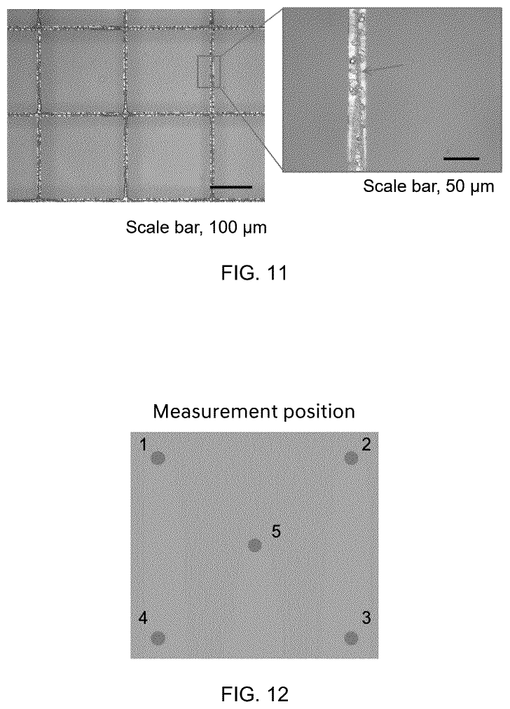

In order to confirm whether the extent of damage to liquid metal was reduced in the transparent electrode for a solar cell manufactured according to the present disclosure, the transparent electrodes according to Example and Comparative Example were observed under an optical microscope. The results of Example are shown in FIG. 10 and the results of Comparative Example are shown in FIG. 11.

When comparing FIGS. 10 and 11, it was confirmed that the transparent electrode manufactured according to the present disclosure was much neater than Comparative Example. Specifically, in the transparent electrode according to Comparative Example, many portions where the surface of the liquid metal was cracked or peeled off were observed. However, such portions could not be observed in the transparent electrode according to Example.

This is deemed to be because, when the upper sacrificial layer with the metal layer deposited thereon is removed using mr-Rem 700 as a sacrificial layer remover solution, in the present disclosure, a metal layer having the grid shape is left on the protective layer including a hydrophobic polymer, thus minimizing the effect of surface tension.

### Test Example 2—Analysis of Sheet Resistance

In order to confirm whether electrical performance of the transparent electrode without any damage to or deformation on the surface of the liquid metal as confirmed in Test Example 1 was superior, sheet resistance of the transparent electrode according to Example and the transparent electrode according to Comparative Example was measured. FIG. 12 shows measurement points of sheet resistance.

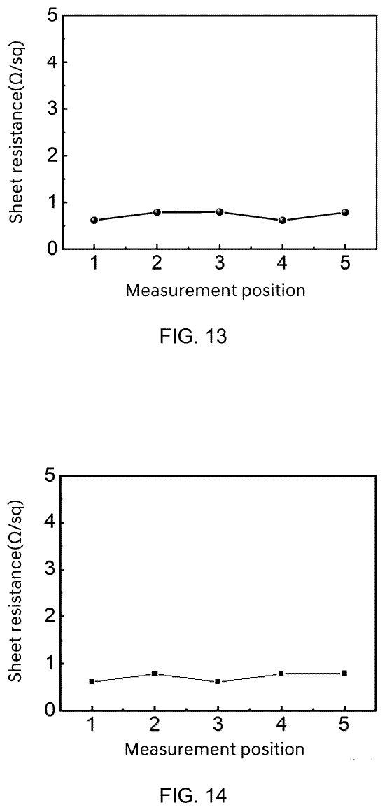

The sheet resistance of the transparent electrode according to Example is shown in FIG. 13, and the sheet resistance of the transparent electrode according to Comparative Example is shown in FIG. 14.

Referring to FIG. 13, in Example in which the transparent electrode was manufactured by introducing the protective layer, the average sheet resistance was measured to be 0.717 Ω/sq. On the other hand, according to FIG. 14, in Comparative Example in which the transparent electrode was manufactured without introducing the protective layer, the average sheet resistance was measured to be 0.972 Ω/sq.

Accordingly, it was confirmed that pattern uniformity increased and sheet resistance decreased when the extent of damage to or deformation on the liquid metal in the transparent electrode decreased.

### Test Example 3—Analysis of Transparency

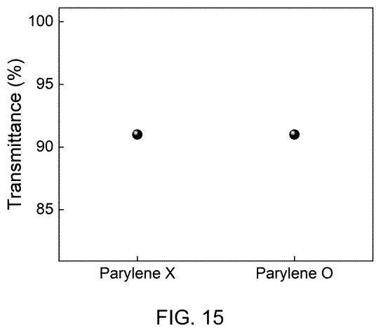

In order to determine transparency of the transparent electrode manufactured according to the present disclosure compared to the conventional electrode, the transmittance (%) of the transparent electrodes according to Example and Comparative Example was measured. The measurement positions are the same as in Test Example 2, and the results for each transmittance are shown in FIG. 15 and Table 1 below.

TABLE 1

| | 1 | 2 | 3 | 4 | 5 | Average |
|---|---|---|---|---|---|---|
| Example (parylene O) | 90.5 | 91.2 | 91.8 | 90.4 | 91.0 | 91 |
| Comparative Example | 90.1 | 91.8 | 91.6 | 90.9 | 90.5 | 91 |
| (parylene X) | | | | | | |

Referring to the numerical values shown in FIG. 15 and Table 1, it was confirmed that the transmittance values of the transparent electrodes were maintained to be 91%, the same as each other, regardless of the introduction of the protective layer.

As is apparent from the above description, a method of manufacturing a transparent electrode for a solar cell according to the present disclosure includes interposing a hydrophobic protective layer between a lower sacrificial layer and an upper sacrificial layer, and thus, when leaving a metal layer having a specific pattern shape on the protective layer, it is possible to prevent a phenomenon in which liquid metal is damaged or deformed by surface tension in another fluid such as a decomposition solution.

Accordingly, when manufacturing a transparent electrode, the process yield can be improved and electrochemical performance thereof can be improved.

In addition, since the metal layer of the transparent electrode for a solar cell manufactured according to the present disclosure includes liquid metal, it has a resistivity value similar to that of general metals and can exhibit excellent electrical properties. Furthermore, the metal layer has a lower Young's modulus than general metals and is able to form an oxide film when exposed to oxygen, manifesting high elasticity and self-healing properties.

The effects of the present disclosure are not limited to the foregoing. It should be understood that the effects of the present disclosure include all effects that can be inferred from the description of the present disclosure.

As the embodiments of the present disclosure have been described above, those skilled in the art will appreciate that various modifications and alterations are possible through change, deletion or addition of components without departing from the scope and spirit of the present disclosure as described in the accompanying claims, which will also be said to be included within the scope of rights of the present disclosure.

What is claimed is:

1. A method of manufacturing a transparent electrode for a solar cell, comprising:
sequentially forming a lower sacrificial layer, a protective layer, and an upper sacrificial layer on a substrate;
exposing a portion of a surface of the protective layer by removing a portion of the upper sacrificial layer in a specific pattern shape;
depositing a metal layer comprising liquid metal on a surface of the remaining upper sacrificial layer and a surface of the protective layer that is exposed;
leaving a metal layer having the specific pattern shape on the protective layer by removing the upper sacrificial layer with the metal layer deposited thereon;
forming a polymer layer to surround the metal layer having the specific pattern shape;
separating the protective layer, the metal layer, and the polymer layer from the substrate by removing the lower sacrificial layer; and
removing the protective layer to manufacture a liquid metal transparent electrode comprising the metal layer and the polymer layer.

2. The method of claim 1, wherein each of the lower sacrificial layer and the upper sacrificial layer comprises a photoresist.

3. The method of claim 1, wherein each of the lower sacrificial layer and the upper sacrificial layer comprises any one selected from the group consisting of lift-off resist (LOR), poly(methyl methacrylate) (PMMA), and combination thereof.

4. The method of claim 1, wherein the protective layer comprises a hydrophobic polymer.

5. The method of claim 1, wherein the protective layer comprises parylene-C.

6. The method of claim 1, wherein a thickness of the protective layer is about 0.5 μm to 3 μM.

7. The method of claim 1, wherein the specific pattern shape comprises a stripe shape, a branch shape, or a grid shape.

8. The method of claim 1, wherein a line width of the specific pattern is about 1 μm to 10 μm.

9. The method of claim 1, wherein the liquid metal comprises a eutectic gallium-indium alloy (EGaIn).

10. The method of claim 1, wherein the polymer layer comprises a transparent elastomer.

11. The method of claim 1, wherein the polymer layer comprises a thermosetting polymer.

12. The method of claim 1, wherein the polymer layer comprises any one selected from the group consisting of polydimethylsiloxane (PDMS), thermoplastic polyurethane elastomer (TPE), and combinations thereof.

13. The method of claim 1, wherein the protective layer is removed by dry etching using oxygen plasma.

14. A method of manufacturing a transparent electrode for a solar cell, comprising:
forming a lower sacrificial layer on a substrate;
forming a protective layer on the lower sacrificial layer;
forming an upper sacrificial layer on the protective layer;
patterning the upper sacrificial layer to expose a portion of the protective layer;
depositing a metal layer comprising liquid metal on the patterned upper sacrificial layer and the exposed portion of the protective layer;
removing the upper sacrificial layer to leave the metal layer in a patterned shape on the protective layer;
forming a polymer layer over the patterned metal layer;
separating the protective layer, the metal layer, and the polymer layer from the substrate by removing the lower sacrificial layer;
removing the protective layer to produce the transparent electrode.

15. The method of claim 14, wherein each of the lower sacrificial layer and the upper sacrificial layer comprises lift-off resist (LOR) or poly(methyl methacrylate) (PMMA).

16. The method of claim 14, wherein the protective layer comprises parylene-C.

17. The method of claim 14, wherein the liquid metal comprises a eutectic gallium-indium alloy (EGaIn).

18. A method of manufacturing a transparent electrode for a solar cell, comprising:
forming a lower sacrificial layer on a substrate;
forming a protective layer on the lower sacrificial layer;
forming an upper sacrificial layer on the protective layer;
patterning the upper sacrificial layer to expose a portion of the protective layer;
depositing a metal layer comprising liquid metal on the patterned upper sacrificial layer and the exposed portion of the protective layer;
forming a polymer layer over the patterned metal layer;
separating the protective layer, the metal layer, and the polymer layer from the substrate by removing the lower sacrificial layer; and
curing the polymer layer to form a transparent elastomeric matrix, thereby forming the transparent electrode.

19. The method of claim 18, wherein the polymer layer is cured using UV light.

20. The method of claim 18, wherein the polymer layer comprises polydimethylsiloxane (PDMS).
